(19) United States
(12) Patent Application Publication
(10) Pub. No.: US 2021/0242318 A1
(43) Pub. Date: Aug. 5, 2021

(54) SEMICONDUCTOR DEVICE

(71) Applicant: DENSO CORPORATION, Kariya-city (JP)

(72) Inventor: Mutsuya MOTOJIMA, Kariya-city (JP)

(21) Appl. No.: 17/238,587

(22) Filed: Apr. 23, 2021

Related U.S. Application Data
(63) Continuation of application No. PCT/JP2019/040579, filed on Oct. 16, 2019.

(30) Foreign Application Priority Data
Nov. 23, 2018 (JP) 2018-219795

(51) Int. Cl. H01L 29/417

(52) U.S. Cl. CPC H01L 29/41775

(57) ABSTRACT

A semiconductor device includes a semiconductor layer, a source region, a drain region, a gate electrode, a first electrode, and a second electrode. The semiconductor layer has a main surface. The semiconductor layer generates a channel close to the main surface along one direction of the main surface. The source region and the drain region are disposed in a surface layer of the semiconductor layer. A portion where the channel is generated is disposed between the source region and the drain region. The gate electrode is disposed above the channel and along the one direction. The first electrode is connected to a region of the main surface corresponding to the source region. The second electrode is connected to a region of the main surface corresponding to the drain region.

### CROSS REFERENCE TO RELATED APPLICATIONS

The present application is a continuation application of International Patent Application No. PCT/JP2019/040579 filed on Oct. 16, 2019, which designated the U.S. and claims the benefit of priority from Japanese Patent Application No. 2018-219795 filed on Nov. 23, 2018. The entire disclosures of all of the above applications are incorporated herein by reference.

### TECHNICAL FIELD

The present disclosure relates to a semiconductor device.

### BACKGROUND

For example, a semiconductor device in which a gate region is disposed between a source region and a drain region has been proposed. The source region has one contact region to be connected to a contact for the source region. The drain region has one contact region to be connected to a contact for the drain region. Each contact is an electrode connected to a wire.

### SUMMARY

The present disclosure provides a semiconductor device. The semiconductor device includes a semiconductor layer, a source region, a drain region, a gate electrode, a first electrode, and a second electrode. The semiconductor layer has a main surface. The semiconductor layer generates a channel close to the main surface along one direction of the main surface. The source region and the drain region are disposed in a surface layer of the semiconductor layer. A portion where the channel is generated is disposed between the source region and the drain region. The gate electrode is disposed above the channel and along the one direction. The first electrode is connected to a region of the main surface corresponding to the source region. The second electrode is connected to a region of the main surface corresponding to the drain region.

### BRIEF DESCRIPTION OF DRAWINGS

The features and advantages of the present disclosure will become more apparent from the following detailed description made with reference to the accompanying drawings. In the drawings:

FIG. 1 is a plan view of a semiconductor device according to a first embodiment;

FIG. 2 is a cross-sectional view taken along a line II-II in FIG. 1;

FIG. 3 is a cross-sectional view taken along a line III-III in FIG. 1;

FIG. 4 is a plan view showing a modified example of a first electrode according to the first embodiment;

FIG. 5 is a plan view of a semiconductor device according to a second embodiment;

FIG. 6 is a plan view showing a modified example of a first electrode according to the second embodiment;

FIG. 7 is a plan view showing a modified example of the first electrode according to the second embodiment;

FIG. 8 is a plan view showing a modified example of the first electrode according to the second embodiment; and

FIG. 9 is a plan view showing a modified example of the first electrode according to the second embodiment.

### DETAILED DESCRIPTION

In the field of semiconductor technology, an inspection such as screening for foreign substance and a measure to reduce a foreign substance in manufacturing processes are being continuously implemented. However, in a configuration where one contact is connected to a source region of a semiconductor device and another contact is connected to a drain of a semiconductor device, when a foreign substance adheres to the contact, the contact may be opened. The inspection method to reduce the failure of contact open has not been established yet. Therefore, it is necessary to reduce the contact open failure itself.

The present disclosure provides a semiconductor device capable of reducing a failure of contact open.

An exemplary embodiment of the present disclosure provides a semiconductor device. The semiconductor device includes a semiconductor layer, a source region, a drain region, a gate electrode, a first electrode, and a second electrode. The semiconductor layer has a main surface. The semiconductor layer generates a channel close to the main surface along one direction of the main surface. The source region and the drain region are disposed in a surface layer of the semiconductor layer. A portion where the channel is generated is disposed between the source region and the drain region. The gate electrode is disposed above the channel and along the one direction. The first electrode is connected to a region of the main surface corresponding to the source region. The second electrode is connected to a region of the main surface corresponding to the drain region. The first electrode has a plurality of first contacts connected to the region of the main surface corresponding to the source region. The second electrode has a plurality of second contacts connected to the region of the main surface corresponding to the drain region. The one direction is defined as a gate width direction of the gate electrode. The plurality of first contacts are arranged in a row along the gate width direction. The plurality of second contacts are arranged in a row along the gate width direction.

In the exemplary embodiment of the present disclosure, since the plurality of first contacts are provided, it is difficult for all of the plurality of first contacts to have contact open. Similarly, since the plurality of second contacts are provided, it is difficult for all of the plurality of second contacts to have contact open. Therefore, the configuration can reduce the failure of contact open.

The following will describe embodiments for carrying out the present disclosure with reference to the drawings. In the respective embodiments, parts corresponding to matters already described in the preceding embodiments are given reference numbers identical to reference numbers of the matters already described. The same description is therefore omitted depending on circumstances. In a case where only a part of the configuration is described in each embodiment, the other embodiments described above can be applied to the other part of the configuration. The present disclosure is not limited to combinations of embodiments which combine parts that are explicitly described as being combinable. As long as no problem is present, the various embodiments may be partially combined with each other even if not explicitly described.

### First Embodiment

Hereinafter, a first embodiment will be described with reference to the drawings. A semiconductor device according to the first embodiment is, for example, an N-type Metal-Oxide-Semiconductor Field-Effect Transistor (MOSFET).

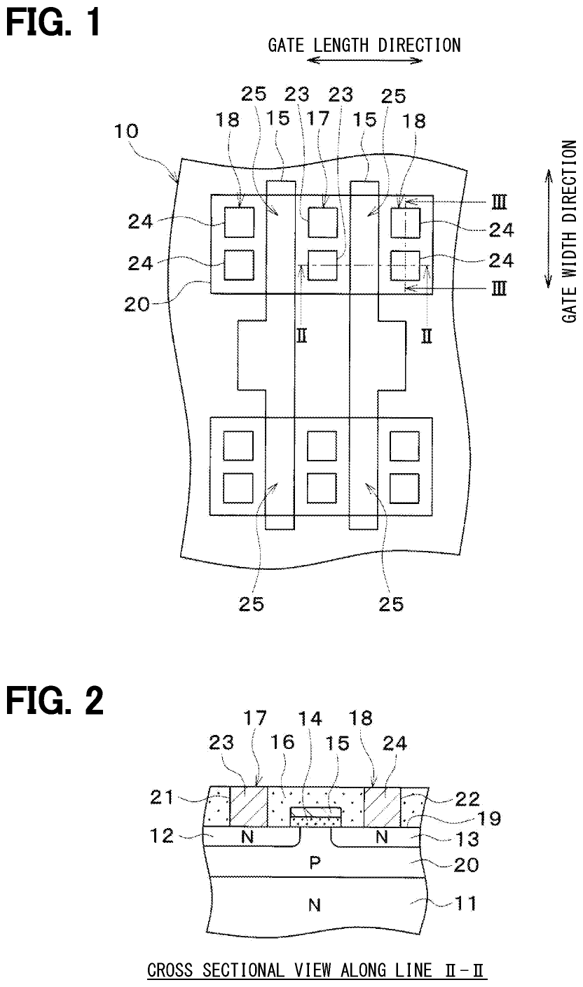

As shown in FIGS. 1 to 3, a semiconductor device 10 includes an N-type semiconductor layer 11, an N-type source region 12, an N-type drain region 13, a gate oxide film 14, a gate electrode 15, an insulating film 16, a first electrode 17, and a second electrode 18.

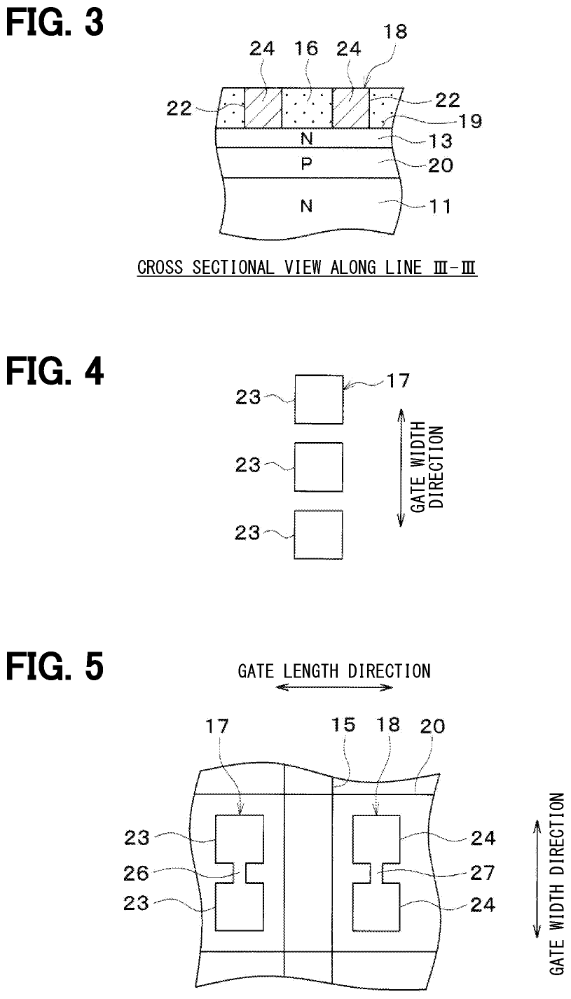

As shown in FIGS. 2 and 3, the semiconductor layer 11 has a main surface 19. The semiconductor layer 11 is, for example, a silicon layer of an SOI substrate. The semiconductor layer 11 may be, for example, a single silicon substrate.

Further, the semiconductor layer 11 has a P-type well region 20. The well region 20 is a constant region formed on a main surface 19 side of the semiconductor layer 11. A channel is generated on the main surface 19 side of the semiconductor layer 11 along one of the directions in the main surface 19 of the semiconductor layer 11. The channel is generated on the main surface 19 side of the well region 20.

The source region 12 and the drain region 13 are N-type regions formed in a surface layer of the semiconductor layer 11. The “surface layer of the semiconductor layer 11” is a region on the main surface 19 side in a thickness direction of the semiconductor layer 11. The surface layer includes the main surface 19. The N-type region electrically connected to the power supply is the drain region 13. The N-type region electrically connected to the ground is the source region 12.

The source region 12 and the drain region 13 are formed on the main surface 19 side of the well region 20 so as to sandwich the portion of the semiconductor layer 11 where channel is generated. That is, the source region 12 and the drain region 13 are apart from each other at regular intervals.

As shown in FIG. 2, the gate oxide film 14 is formed in a region of the main surface 19 of the semiconductor layer 11 where the channel is generated. The gate oxide film 14 is formed by an oxidation treatment of the main surface 19 of the semiconductor layer 11. The gate oxide film 14 is, for example, an insulating film such as SiO₂.

The gate electrode 15 is formed on the gate oxide film 14. That is, the gate electrode 15 is formed above the channel. When the gate voltage is applied to the gate electrode 15, the channel is generated in the surface layer of the semiconductor layer 11. This configuration causes current to flow between the drain and source.

Further, as shown in FIG. 1, the gate electrode 15 is formed along one direction in a plane of the main surface 19 of the semiconductor layer 11. That is, the gate electrode 15 is arranged in a straight line. The gate electrode 15 is, for example, polysilicon. Polysilicon is formed, for example, by the CVD method.

One direction in the plane of the main surface 19 of the semiconductor layer 11 is defined as a gate width direction of the gate electrode 15. Further, another direction, in the plane of the main surface 19 of the semiconductor layer 11, perpendicular to the gate width direction is defined as a gate length direction. The source region 12 and the drain region 13 are formed along the gate width direction and are located apart from each other in the gate length direction.

As shown in FIGS. 2 and 3, the insulating film 16 is mainly formed on the main surface 19 of the semiconductor layer 11. The insulating film 16 covers the regions corresponding to the source region 12 and the drain region 13, the gate oxide film 14, and the gate electrode 15 in the main surface 19 of the semiconductor layer 11. The insulating film 16 is, for example, a silicon oxide film. The insulating film 16 is formed, for example, by the CVD method.

Further, the insulating film 16 has a plurality of holes 21 and 22. The holes 21 and 22 are contact holes. Two first holes 21 are provided. The first hole 21 leads to a region corresponding to the source region 12 in the main surface 19 of the semiconductor layer 11. The two first holes 21 are arranged in a row along the gate width direction of the gate electrode 15.

Two second holes 22 are provided. The second hole 22 leads to a region corresponding to the drain region 13 in the main surface 19 of the semiconductor layer 11. The two second holes 22 are arranged in a row along the gate width direction of the gate electrode 15. The insulating film 16 also has a contact hole (not shown) leading to the gate electrode 15.

The first electrode 17 is an electrode for a source. The first electrode 17 is connected to a region corresponding to the source region 12 of the main surface 19 of the semiconductor layer 11. The first electrode 17 has two first contacts 23 connected to a region corresponding to the source region 12.

The two first contacts 23 are each buried in the two first holes 21. That is, as shown in FIG. 1, the two first contacts 23 are arranged in a row along the gate width direction of the gate electrode 15. In other words, in the gate length direction, the distance from the gate electrode 15 to one first contact 23 and the distance from the gate electrode 15 to the other first contact 23 are the same.

In the present embodiment, the two first contacts 23 are arranged apart from each other along the gate width direction of the gate electrode 15. That is, the two first contacts 23 are arranged apart along the gate width direction.

The second electrode 18 is an electrode for a drain. The second electrode 18 is connected to a region corresponding to the drain region 13 of the main surface 19 of the semiconductor layer 11. The second electrode 18 has a plurality of second contacts 24 connected to the region corresponding to the drain region 13.

The two second contacts 24 are each buried in the two second holes 22. That is, the two second contacts 24 are arranged in a row along the gate width direction of the gate electrode 15. In the gate length direction, the distance from the gate electrode 15 to one second contact 24 and the distance from the gate electrode 15 to the other second contact 24 are the same. The two second contacts 24 are arranged apart from each other along the gate width direction of the gate electrode 15.

The planar shape of each of the contacts 23 and 24 is, for example, a square. The planar shape of each of the contacts 23 and 24 may be a rectangular. Each of the contacts 23 and 24 is, for example, a metal material such as Al, Cu, W, or the like. Each of the contacts 23 and 24 is connected to a wiring (not shown). Each of the contacts 23 and 24 is formed by, for example, a CVD method.

As shown in FIG. 1, in the present embodiment, two gate electrodes 15 are formed in the gate length direction. Further, the well regions 20 are formed at two locations apart from each other in the gate width direction. In the plane of the main surface 19 of the semiconductor layer 11, the two well regions 20 intersect the two gate electrodes 15.

In one well region 20, the source region 12 is located between the two gate electrodes 15 of the well region 20. The drain region 13 is formed at a position of the well region 20 that is not disposed between the two gate electrodes 15. That is, two semiconductor elements 25 are formed in the gate length direction. The source region 12 is common to the two semiconductor elements 25.

The other well region 20 has the similar structure. Therefore, in FIG. 1, four semiconductor elements 25 are shown as one cell. The cell may be configured as a digital cell or an analog cell.

As described above, since the semiconductor device 10 is provided with two first contacts 23, it is difficult for both of the first contacts 23 to be contact open. Similarly, since the two second contacts 24 are provided, it is difficult for both of the second contacts 24 to be contact open. Therefore, the configuration can reduce the failure of contact open in the semiconductor device 10.

The inventors of the present disclosure formed a large number of semiconductor devices 10 provided with two contacts 23 and 24, and investigated the number of semiconductor devices 10 having contact open. As a result, the number of semiconductor devices 10 having contact open was almost zero. That is, it was found that the failure of contact open can be reduced.

Further, it is known that temperature characteristics occur such as an increase in switching time as the temperature of the semiconductor layer 11 rises when a current flows through the semiconductor layer 11. The contacts 23 and 24 are arranged in a row in the gate width direction. In other words, since the distance from the gate electrode 15 to each first contact 23 is the same in the gate length direction, the range in which the current flows in the gate length direction can be minimized. That is, the range in which heat is generated in the gate length direction can be minimized. Therefore, even when the number of the contacts 23 and 24 is two, it is possible to provide the semiconductor device 10 having strong temperature characteristics.

Further, since the semiconductor device 10 is provided with the two contacts 23 and two contacts 24, it is possible to obtain the semiconductor device 10 which is more resistant to manufacturing variation than the case where one contact is provided. Further, even when one of the two first contacts 23 is opened, the electrical connection of the other one of the two first contacts 23 can be maintained. Therefore, the configuration can inhibit a decrease in the operation speed of the semiconductor element 25.

As a modification, as shown in FIG. 4, the first electrode 17 may have three first contacts 23. In this case, three first contacts 23 are provided in a row along the gate width direction. Further, the number of the first contacts 23 is not limited to three. The number of the first contacts 23 may be four or more. The same applies to the second electrode 18.

### Second Embodiment

In the present embodiment, portions different from those of the first embodiment will be mainly described. As shown in FIG. 5, the first electrode 17 has a first connection 26. The first connection 26 is an electrode having a width narrower than the width of the first contact 23 in the gate length direction. The first connection 26 connects one first contact 23 and the other first contact 23. The first connection 26 is connected to the center of each first contact 23 in the gate length direction.

Further, the second electrode 18 has a second connection 27. The second connection 27 is an electrode having a width narrower than the width of the second contact 24 in the gate length direction. The second connection 27 connects one second contact 24 and the other second contact 24. The second connection 27 is connected to the center of each second contact 24 in the gate length direction.

Each of the connections 26 and 27 is buried in a contact hole formed in the insulating film 16. The first connection 26 is connected to the source region 12. The second connection 27 is connected to the drain region 13.

Therefore, the two first contacts 23 are connected in the gate width direction by the first connection 26. Further, the two second contacts 24 are connected in the gate width direction by the second connection 27. As a result, the connection area between the wiring and each of the contacts 23 and 24 is increased by the area of the connections 26 and 27. Thus, the failure of contact open can be further reduced.

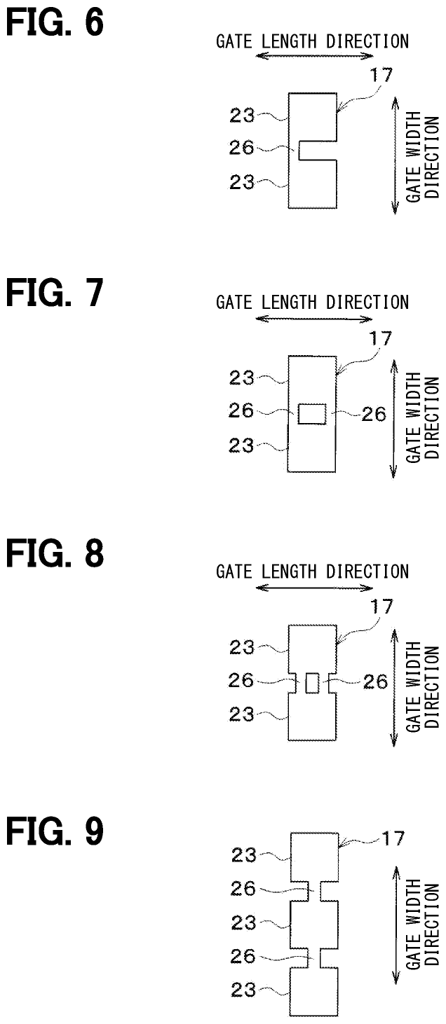

As a modification, as shown in FIG. 6, the first connection 26 may be connected to one end of each first contact 23 in the gate length direction. The first connection 26 may be connected to the other end of each first contact 23 in the gate length direction. This configuration also applies to the second contact 24.

As a modification, the first electrode 17 may have a plurality of first connections 26. For example, as shown in FIG. 7, two first connections 26 are connected to both ends of each first contact 23 in the gate length direction. Alternatively, as shown in FIG. 8, the two first connections 26 are connected to positions other than both ends of each first contact 23 in the gate length direction. The number of the first connections 26 is not limited to two. The number of the first connections 26 may be three or more. The same applies to the second electrode 18.

As a modification, as shown in FIG. 9, the three first contacts 23 may be adjacent to each other by the first connection 26 in the gate width direction. The connection method may be the same as the methods shown in FIGS. 6 to 8. The configuration can also be applied to four or more first contacts 23. This configuration also applies to the second contact 24.

The present disclosure is not limited to the embodiments described above, and various modifications can be made as follows within a range not departing from the spirit of the present disclosure.

For example, the semiconductor device 10 is not limited to the element structure shown in FIGS. 2 and 3. The MOSFET may be configured as a P type. Further, an N+type region for contact may be formed in the source region 12 and the drain region 13. In this case, each of the contacts 23 and 24 is connected to the contact region.

In each of the above embodiments, each of the number of contacts 23 and the number of contacts 24 is two, however the number of contacts 23 and the number of contacts 24 may not be the same. Each of the contacts 23 and 24 may have a plurality of numbers and may be set to a different number.

Although the present disclosure has been described in accordance with the embodiments, it is understood that the present disclosure is not limited to the embodiments and structures disclosed therein. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

What is claimed is:

1. A semiconductor device comprising:
a semiconductor layer having a main surface and configured to generate a channel close to the main surface along one direction of the main surface;
a source region;
a drain region, wherein the source region and the drain region are disposed in a surface layer of the semiconductor layer, and a portion where the channel is generated is disposed between the source region and the drain region;
a gate electrode disposed above the channel and along the one direction;
a first electrode connected to a region of the main surface corresponding to the source region; and
a second electrode connected to a region of the main surface corresponding to the drain region, wherein
the first electrode has a plurality of first contacts connected to the region of the main surface corresponding to the source region,
the second electrode has a plurality of second contacts connected to the region of the main surface corresponding to the drain region,
the one direction is defined as a gate width direction of the gate electrode,
the plurality of first contacts are arranged in a row along the gate width direction, and
the plurality of second contacts are arranged in a row along the gate width direction.

2. The semiconductor device according to claim 1, wherein
the plurality of first contacts are arranged apart from each other, and
the plurality of second contacts are arranged apart from each other.

3. The semiconductor device according to claim 1, wherein
another direction of the main surface perpendicular to the gate width direction is defined as a gate length direction,
the first electrode includes a first connection having a width narrower than a width of each of the plurality of first contacts in the gate length direction,
two of the plurality of first contacts adjacent to each other are connected via the first connection in the gate width direction,
the second electrode includes a second connection having a width narrower than a width of each of the plurality of second contacts in the gate length direction, and
two of the plurality of second contacts adjacent to each other are connected via the second connection in the gate width direction.

4. The semiconductor device according to claim 1, wherein
a number of the plurality of first contacts is two, and
a number of the plurality of second contacts is two.
